(19) United States
(12) Patent Application Publication
(10) Pub. No.: US 2009/0151778 A1
(43) Pub. Date: Jun. 18, 2009

(54) SOLAR ENERGY PHOTOVOLTAIC CONTROL SYSTEM

(75) Inventor: CHIA-HUNG WANG, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/965,761

(22) Filed: Dec. 28, 2007

(30) Foreign Application Priority Data
Dec. 13, 2007 (CN) 200710203036.X

(51) Int. Cl. H01L 31/04; H02J 7/00

(52) U.S. Cl. 136/252; 320/101

(57) ABSTRACT

A solar energy photovoltaic (PV) control system includes a solar energy absorption board configured to receive solar energy from solar rays and transfer solar energy to voltage/current signals, a motor, a voltage/current collecting circuit connected to the solar energy absorption board to receive the voltage/current signals therefrom, a micro control unit (MCU) connected to the voltage/current collecting circuit to receive the voltage/current signals therefrom, and a motor driver connected between the MCU and the motor. The solar energy absorption board is fixed on the motor and the motor drives the solar energy absorption board to pivot. The MCU controls the motor driver to drive the motor to adjust the angle between incoming solar rays and the solar energy absorption board to place the solar energy absorption board to directly face the sun according to the collected voltage/current signals.

### BACKGROUND

1. Field of the Invention

The present invention relates to solar energy photovoltaic (PV) control systems, and particularly to a solar energy PV system which can automatically adjust the angle between solar rays and a solar energy absorption board.

2. Description of Related Art

Referring to FIG. 1, a conventional solar energy PV system is illustrated. The solar energy PV system includes a solar energy absorption board 100, a control unit 200 having a voltage/current collecting circuit 220 and a maximum power point tracking (MPPT) control circuit 240, and a storage battery 300. The solar energy absorption board 100 receives solar energy and transforms the solar energy to voltage/current signals. The voltage/current collecting circuit 220 receives the voltage/current signals and transmits them to the MPPT control circuit 240. The MPPT control circuit 240 receives the voltage/current signals and performs some predetermined MPPT control algorithms such as perturbation and observation MPPT method, so that the photovoltaic arrays are able to deliver maximum available power to the storage battery 300. However, the conventional solar energy PV system only can adjust the voltage/current signal, but cannot adjust the angle between the incoming solar rays and the solar energy absorption board to achieve maximum absorption efficiency.

What is desired, therefore, is to provide a solar energy photovoltaic (PV) control system which can automatically adjust the angle between incoming solar rays and a solar energy absorption board.

### SUMMARY

An embodiment of a solar energy photovoltaic (PV) control system includes a solar energy absorption board configured to receive solar energy from solar rays and transfer solar energy to voltage/current signals, a motor, a voltage/current collecting circuit connected to the solar energy absorption board to receive the voltage/current signals therefrom, a micro control unit (MCU) connected to the voltage/current collecting circuit to receive the voltage/current signals therefrom, and a motor driver connected between the MCU and the motor. The solar energy absorption board is fixed on the motor and the motor drives the solar energy absorption board to pivot. The MCU controls the motor driver to drive the motor to adjust the angle between incoming solar rays and the solar energy absorption board to place the solar energy absorption board to directly face the sun according to the collected voltage/current signals.

Other advantages and novel features of the present invention will become more apparent from the following detailed description of an embodiment when taken in conjunction with the accompanying drawings, in which:

### BRIEF DESCRIPTION OF THE DRAWINGS

FIG. 1 is a block diagram of a conventional solar energy PV control system;

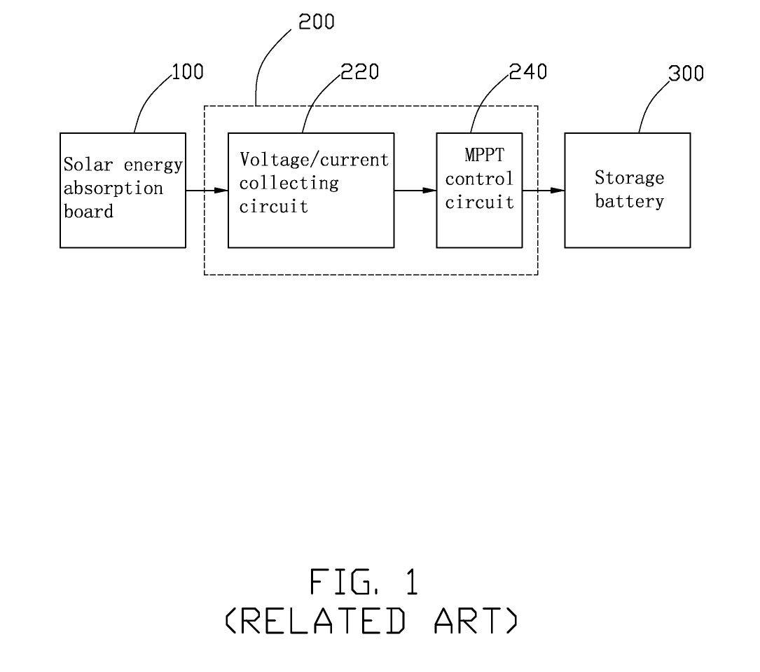

FIG. 2 is a block diagram of a solar energy PV control system in accordance with an embodiment of the present invention; and

FIG. 3 is a schematic view of a motor driving a solar energy absorption board to pivot of the solar energy PV control system of FIG. 2.

### DETAILED DESCRIPTION

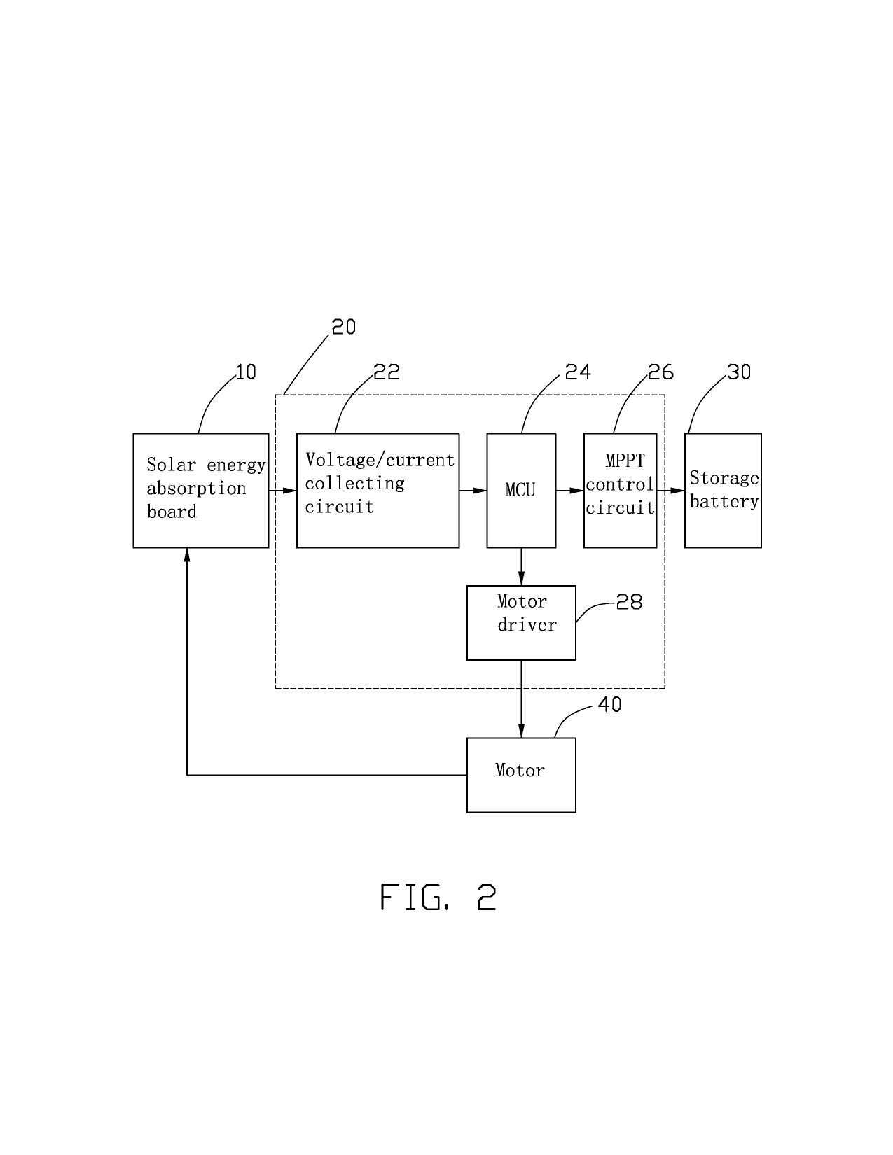

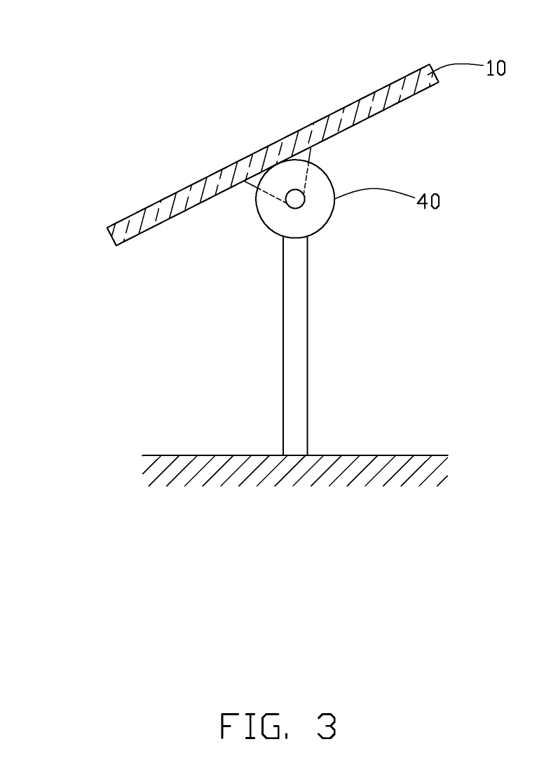

Referring to FIGS. 2 and 3, a solar energy photovoltaic (PV) control system in accordance with an embodiment of the present invention includes a solar energy absorption board 10, a control unit 20, a storage battery 30, and a motor 40. The control unit 20 includes a voltage/current collecting circuit 22, a micro control unit (MCU) 24, a MPPT control circuit 26, and a motor driver 28. The solar energy absorption board 10 is fixed on the motor 40, and the motor 40 can drive the solar energy absorption board 10 to pivot via the motor driver 28.

The solar energy absorption board 10 is configured to receive solar energy and transform the solar energy to voltage/current signals. An input of the voltage/current collecting circuit 22 is connected to the solar energy absorption board 10 to receive voltage/current signals from the solar energy absorption board 10. An input of the MCU 24 is connected to an output of the voltage/current collecting circuit 22 to receive the voltage/current signals from the voltage/current collecting circuit 22. The MCU 24 controls the motor driver 28 to drive the motor 40 to adjust the angle between incoming solar rays and the solar energy absorption board 10 to place the solar energy absorption board 10 to directly face the sun according to the collected voltage/current signals. An output of the MCU 24 outputs the adjusted voltage/current signals to the MPPT control circuit 26 after the solar energy absorption board 10 being adjusted. Then, the MPPT control circuit 26 receives the adjusted voltage/current signals and performs some predetermined MPPT control algorithms, so that the photovoltaic arrays are able to deliver maximum available power to the storage battery 300 when the solar energy absorption board 10 directly faces the sun.

In this embodiment, the MCU 24 controls the motor driver 28 to drive the motor 40 to adjust the angle between incoming solar rays and the solar energy absorption board 10 about once every thirty minutes. Each time of adjusting the solar energy absorption board 10, the MCU 24 controls the motor driver 28 to drive the motor 40 to pivot the solar energy absorption board 10 through a full range of motion (i.e. from a position where the board 10 faces the sun at the morning horizon to a position where the board faces the sun at the evening horizon) to seek a position where the solar energy absorption board 10 directly faces the sun, at which point the voltage/current signals from the voltage/current collecting circuit 22 are at a maximum level. Once the position is determined, the MCU 24 controls the motor driver 28 to drive the motor 40 to place the solar energy absorption board 10 at that position.

In this solar energy PV control system, because the solar energy absorption board 10 directly faces the sun, thereby, the solar energy PV control system has a maximal absorption efficiency for absorbing solar energy.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A solar energy photovoltaic (PV) control system, comprising:
a solar energy absorption board configured to receive solar rays and transform the energy derived therefrom into voltage/current signals;
a motor, the solar energy absorption board fixed on the motor, the motor driving the solar energy absorption board to pivot;
a voltage/current collecting circuit connected to the solar energy absorption board to receive the voltage/current signals therefrom;
a micro control unit (MCU) connected to the voltage/current collecting circuit to receive the voltage/current signals therefrom; and
a motor driver connected between the MCU and the motor, the MCU controlling the motor driver to drive the motor to adjust the angle between incoming solar rays and the solar energy absorption board to place the solar energy absorption board to directly face the sun according to the collected voltage/current signals.

2. The solar energy PV control system as claimed in claim 1, further comprising a maximum power point tracking (MPPT) control circuit receiving the adjusted voltage/current signals and performs predetermined MPPT control algorithms, so that the photovoltaic arrays are able to deliver maximum available power to a storage battery.
